(19) United States
(12) Patent Application Publication
(10) Pub. No.: US 2011/0278054 A1
(43) Pub. Date: Nov. 17, 2011

(54) CIRCUIT BOARD WITH NOTCHED CONDUCTOR PADS

(76) Inventors: I-Tseng Lee, Kaohsiung City (TW); Yi-Hsiu Liu, Renwu Township (TW); Jen-Yi Tsai, Taichung City (TW)

(21) Appl. No.: 12/780,499

(22) Filed: May 14, 2010

(51) Int. Cl. H05K 1/16; H05K 3/34; H05K 1/00

(52) U.S. Cl. 174/260; 174/250; 29/843; 29/840

(57) ABSTRACT

Various circuit board conductor structures and methods of making the same are disclosed. In one aspect, a method of manufacturing is provided. The method includes forming a first conductor pad on a circuit board. The first conductor pad includes a first notch and is adapted to couple to a first solder portion.

### BACKGROUND OF THE INVENTION

1. Field of the Invention

This invention relates generally to semiconductor processing, and more particularly to methods and apparatus for connecting components to a circuit board.

2. Description of the Related Art

All integrated circuits require electrical power to operate, and packaged integrated circuits, one form which consists of a semiconductor chip mounted on a package substrate, are no exception. Power is normally delivered to integrated circuits via a power supply and some form of power delivery network. Although currently-available power supplies are designed to supply stable voltages, the actual power delivered to integrated circuits can contain significant amounts of noise. There are many sources of noise, such as voltage fluctuations caused by other devices coupled to the power supply, electromagnetic interference and other causes.

Packaged integrated circuits often use decoupling capacitors to lower noise on the power supply. Some of these decoupling capacitors are located on the package substrate. A typical conventional decoupling capacitor consists of a stack of plates commonly connected to two terminals. The capacitor is mounted to a package substrate by way of a pair of solder capacitor pads: one for each terminal. The capacitor pads are positioned on and electrically connected to corresponding conductor pads. The conductor pads are connected to various conductor lines or traces in the substrate that link up electrically with the semiconductor chip.

In a typical conventional substrate, multiple conductor pads are fabricated with different sizes tailored to match different physical sizes of capacitors. Conventional solder capacitor pads are sized to closely match both the sizes and footprints of the underlying conductor pads. For example, two large solder pads are fabricated on two large underlying conductor pads to accommodate a large two terminal capacitor. Conversely, two small solder pads are fabricated on two small underlying conductor pads to accommodate a small two terminal capacitor. In either case, the conventional capacitor pad is formed as a continuous structure, that is, a four-sided rectangle or square.

To connect a capacitor to a pair of conventional rectangular conductor pads, a solder mask is formed over the conductor pads with one opening over each of the conductor pads. A solder paste is dispensed in the openings, the terminals of the capacitor are positioned on the solder paste portions and a reflow is performed to bond the solder portions to their respective conductor pads and capacitor terminals.

During reflow, the solder paste on adjacent conductor pads temporarily liquefies and liberates flux and other solvents. At this stage, the solder exerts attractive forces on the terminals of the capacitor. The magnitude of the force exerted by the solder is a function of the wetting areas between the solder the conductor pad and the solder and the capacitor terminal. If the wetting areas of two adjacent conductor pads and solder portions is equal, then the force exerted on each capacitor terminal will be the same. If, however, the wetting areas are different, then the forces may be unequal and lead to a moment exerted on the capacitor. The wetting areas may be different due to variations in the dimensions of the conductor pads, the solder mask openings, the solder portions or all three. If the moment is large enough to overcome the weight of the capacitor, rotation can occur and lead to poor or no contact between a capacitor terminal and a solder portion. An open circuited capacitor is a problematic defect that may require costly scrapping or reworks.

One conventional technique for addressing the problem of asymmetric solder forces on circuit board capacitors involves trying to more tightly control capacitor terminal width. Another conventional technique attempts to optimize solder mask opening position and size. A third conventional technique looks to solder stencil quality control measures. These techniques may not eliminate the occurrence of defects.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided. The method includes forming a first conductor pad on a circuit board. The first conductor pad includes a first notch and is adapted to couple to a first solder portion.

In accordance with another aspect of an embodiment of the present invention, a method of manufacturing is provided that includes forming a first conductor pad and a second conductor pad on a circuit board. The first conductor pad is adapted to couple to a first solder portion and includes a first notch facing toward the second conductor pad. The second conductor pad is adapted to couple to a second solder portion and includes a second notch facing toward the first conductor pad.

In accordance with another aspect of an embodiment of the present invention, an apparatus is provided that includes a circuit board and a first conductor pad coupled to the circuit board. The first conductor pad includes a first notch and is adapted to couple to a first solder portion.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that includes a semiconductor chip mounted to a circuit board;

FIG. 2 is a plan view of the exemplary semiconductor chip device;

FIG. 3 is a plan view of a small portion of FIG. 2 shown at greater magnification;

FIG. 4 is a plan view like FIG. 3 but at slightly greater magnification and with some elements exploded;

FIG. 5 is a pictorial view of an exemplary conductor pad;

FIG. 6 is a sectional view of FIG. 4 taken at section 6-6;

FIG. 7 is a sectional view of FIG. 4 taken at section 7-7;

FIG. 8 is a sectional view of a conventional capacitor surface mounted to a conventional circuit board by soldering;

FIG. 9 is a sectional view of the capacitor and circuit board of FIG. 8 taken at a section orthogonal to FIG. 8;

FIG. 10 is pictorial view of a portion of the convention circuit board that includes two conventionally mounted capacitors;

FIG. 11 is a sectional view depicting exemplary fabrication of a circuit board conductor pad and mask layer;

FIG. 12 is a sectional view like FIG. 11 depicting application of solder on the conductor pad;

FIG. 13 is a sectional view like FIG. 12 depicting placement of an exemplary electronic component on the solder;

FIG. 14 is a sectional view like FIG. 13 depicting a reflow of the solder;

FIG. 15 is a plan view of an alternate exemplary circuit board with alternate exemplary conductor pads; and

FIG. 16 is a plan view of a few alternate exemplary notched conductor pads.

### DETAILED DESCRIPTION OF SPECIFIC EMBODIMENTS

Various embodiments of a circuit board and conductor pads capable of use therewith are disclosed. In one aspect, a circuit board includes conductor pads suitable for solder attachment of electronic components, such as passive devices. The conductor pads include one or more notches that locally inhibit solder wetting during reflow. The locally inhibited solder wetting results in smaller solder volumes, which in turn, decreases the propensity for asymmetric forces acting on terminals of a passive device during reflow. Defects such as tombstones may be avoided.

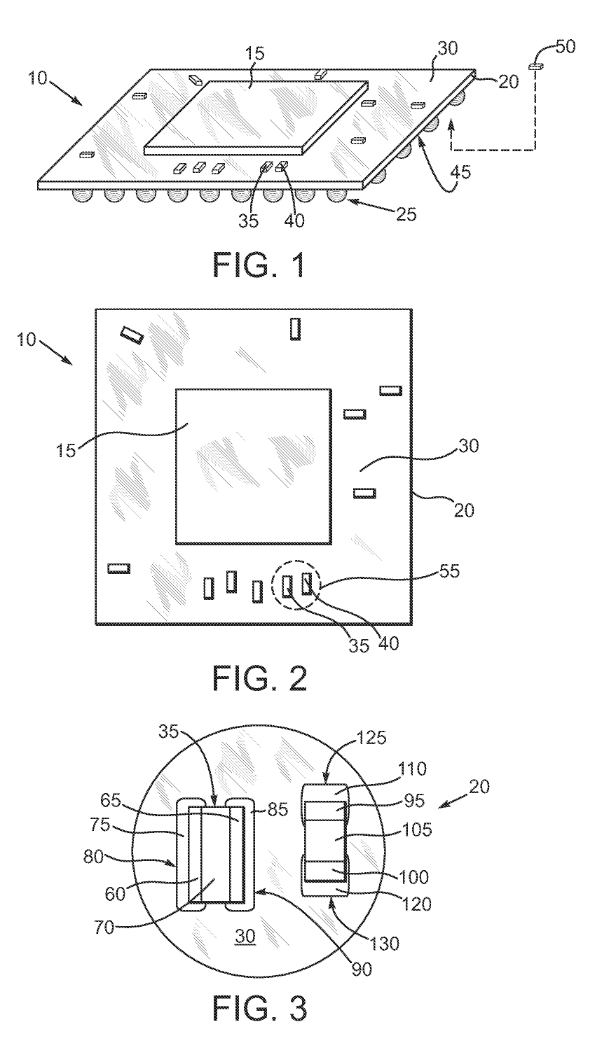

In the drawings described below, reference numerals are generally repeated where identical elements appear in more than one figure. Turning now to the drawings, and in particular to FIG. 1 therein is depicted a pictorial view of an exemplary embodiment of a semiconductor chip device 10 that includes a semiconductor chip 15 mounted on a circuit board 20. The semiconductor chip 15 may be electrically connected to the circuit board 20 by way of way of flip-chip solder joints, flip-chip conductive pillars with or without solder enhancement, wire bonds, combinations of these or other interconnect systems as desired (not shown). The skilled artisan will appreciate that virtually any type of packaging and/or mounting scheme for connecting integrated circuits to a circuit board may be used. The surface 30 of the circuit board 20 may be populated with one or more electronic devices, which may be passive elements such as capacitors, inductors or resistors, or active elements such as transistors or even other integrated circuits. Here, several of the electronic devices are depicted on the surface 30, and two in particular are labeled 35 and 40. It should also be appreciated that the electronic devices, such as the device 50, could be mounted to the opposite surface 45 of the circuit board 20 or both the surfaces 30 and 45. If the circuit board 20 is configured to be mounted to another electronic device, such as another circuit board (not shown), then an interconnect system, such as the depicted ball grid array 25, may be fabricated on the surface 45. Optionally, a pin grid array, a land grid array or other type of interconnect system may be used.

The semiconductor chip 15 may be any of a myriad of different types of circuit devices used in electronics, such as, for example, microprocessors, graphics processors, combined microprocessor/graphics processors, application specific integrated circuits, memory devices or the like, and may be single or multi-core. Multiple planar and/or stacked dice may be used. The semiconductor chip 15 may be fabricated using silicon, germanium or other semiconductor materials. If desired, the semiconductor chip 15 may be fabricated as a semiconductor-on-insulator substrate or as bulk semiconductor.

The circuit board 20 may be configured as a semiconductor chip package substrate, a circuit card, a motherboard or virtually any type of circuit board. Various materials may be used, such as ceramics or organic materials as desired. If organic, the circuit board 20 may be monolithic or consist of multiple layers of metallization and dielectric materials. The circuit board 20 may interconnect electrically with external devices, such as a socket, in a variety of ways, such as the depicted pin grid array 30, or optionally a land grid array, a ball grid array or other configuration. The number of individual layers for the circuit board 20 is largely a matter of design discretion. In certain exemplary embodiments, the number of layers may vary from two to sixteen. If such a build-up design is selected, a standard core, thin core or coreless arrangement may be used. The dielectric materials may be, for example, epoxy resin with or without fiberglass fill. The circuit board 20 may be provided with a number of conductor traces and vias and other structures (not visible) in order to provide power, ground and signals transfers between the semiconductor chip 15 and another device, such as another circuit board for example, and between the electronic components 35, 40 and 50 and other nodes or devices.

Attention is now turned briefly to FIG. 2, which is a plan view of the semiconductor chip device 10. The description herein of the electronic devices 35 and 40 may typify the other similar electronic devices. The electronic devices 35 and 40 may be arranged around the periphery of the semiconductor chip 15 in a myriad of configurations. Furthermore, the number of the electronic devices 35 and 40 may vary greatly from one to hundreds or more depending upon the complexity of the circuit board 20 and the semiconductor chip 15. Note the location of the dashed circle 55 which circumscribes the portion of the circuit board 20 that includes the electrical components 35 and 40. That portion circumscribed by the dashed circle 55 will be shown at greater magnification in FIG. 3.

Attention is now turned to FIG. 3. In this illustrative embodiment, the electrical components 35 and 40 may be capacitors. The capacitor 35 may include a pair of terminals 60 and 65 that bracket a central plate portion 70. The terminals 60 and 65 are typically exposed conducting material while the plate portion 70 may be encased in insulating material such as a baked green tape, epoxy or other resin materials suitable for use in forming capacitors. The terminal 60 is metallurgically bonded to a solder portion 75 that is positioned in an opening 80 in the surface 30 of the circuit board 20. As described more fully below, the surface 30 is actually the upper surface of an insulating layer, which may be a solder mask or other type of insulating layer. The terminal 65 is similarly metallurgically bonded to a solder portion 85 that is positioned in an opening 90 of the surface 30 of the circuit board 20. In a simple form, the capacitor 35 may consist of two parallel plates (not shown) separated by a dielectric. However, the number of plates may be varied as desired.

The capacitor 40 may similarly include terminals 95 and 100 that bracket a plate portion 105. The terminals 95 and 100 are metallurgically bonded to corresponding solder portions 110 and 120 that are, in turn, positioned in corresponding openings 125 and 130 of the surface 30 of the circuit board 20. The solder portions 75, 85, 110 and 120 are metallurgically connected to corresponding conductor pads of the circuit board 20 which are not visible in FIG. 3 but will be shown in subsequent figures.

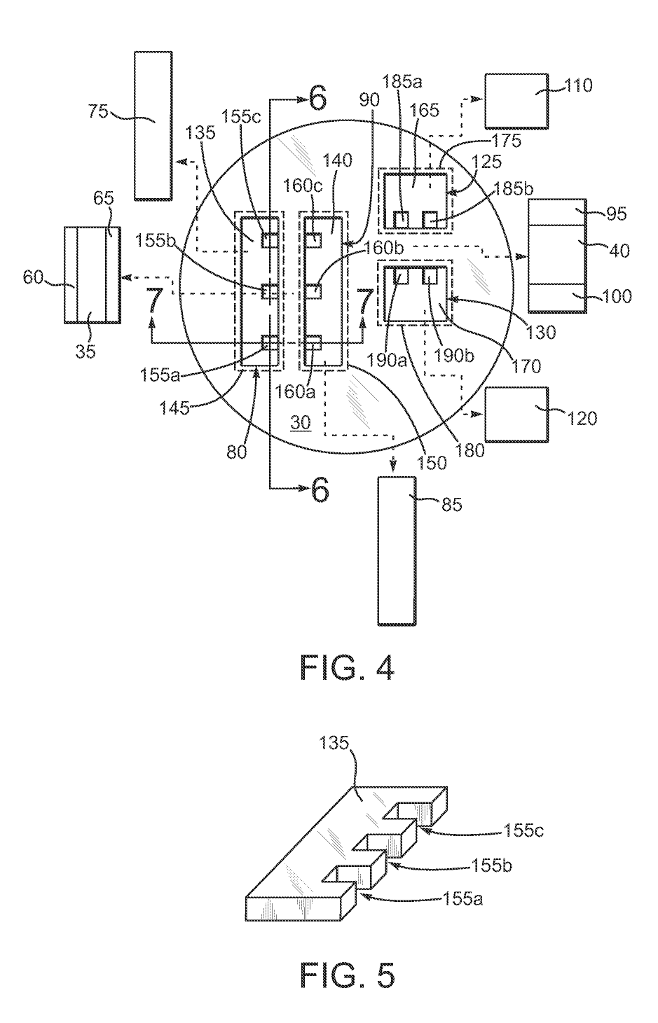

Attention is now turned to FIG. 4. FIG. 4 is the same plan view of the portion of the circuit board 20 depicted in FIG. 3, albeit at a slightly larger magnification and with the solder portions 75, 85, 110 and 120 removed from the circuit board 20 and the capacitors 35 and 40 exploded from the solder portions 75, 85, 110 and 120. With the solder portions 75 and 85 exploded from their respective openings 80 and 90 in the surface 30, underlying conductor pads 135 and 140 of the circuit board 20 are revealed. The openings 80 and 90 may be slightly smaller than the footprints of the pads 135 and 140 which are shown in phantom 145 and 150. Unlike conventional conductor pads used to connect to passive components, which would be configured as a continuous rectangular conductor structure, the conductor pads 135 and 140 are patterned with slots or notches 155a, 155b and 155c, and 160a, 160b and 160c, respectively. As described in more detail below, the notches 155a, 155b and 155c and 160a, 160b and 160c are designed to reduce the propensity for the solder portions 75 and 85 to impart asymmetric forces on the terminals 60 and 65 of the capacitor 35 which can lead to the types of defects discussed in the Background section above. The openings 125 and 130 in the surface 30 similarly reveal conductor pads 165 and 170 which are metallurgically bonded to the solder portions 110 and 120, respectively. Here again, the openings 125 and 130 are slightly smaller than the footprints 175 and 180 of the pads 165 and 170 shown in phantom. Like the conductor pads 135 and 140, the conductor pads 165 and 170 may be provided with respective notches 185a, 185b and 190a, 190b that are designed to reduce the potential for asymmetric forces exerted by the solder portions 110 and 120 on the terminals 95 and 100 of the capacitor 40.

Additional details of the conductor pad 135 may be understood by referring now also to FIG. 5, which is a pictorial view of the conductor pad 135 removed from the circuit board 20 shown in FIG. 4. The notches 155a, 155b and 155c of the conductor pad 135 reduce the available area to which the solder portion 75 depicted in FIG. 4 may wet and metallurgically bond, and thus reduce the overall volume of the solder portion 75 which aids in reducing asymmetric forces. The skilled artisan will appreciate that the conductor pads 135, 140, 165 and 170 may take on other than rectangular configurations and may have various numbers of notches. Furthermore, the notches, for example, the notches 155a, 155b and 155c, may be rectangular as shown or virtually any other shape as desired.

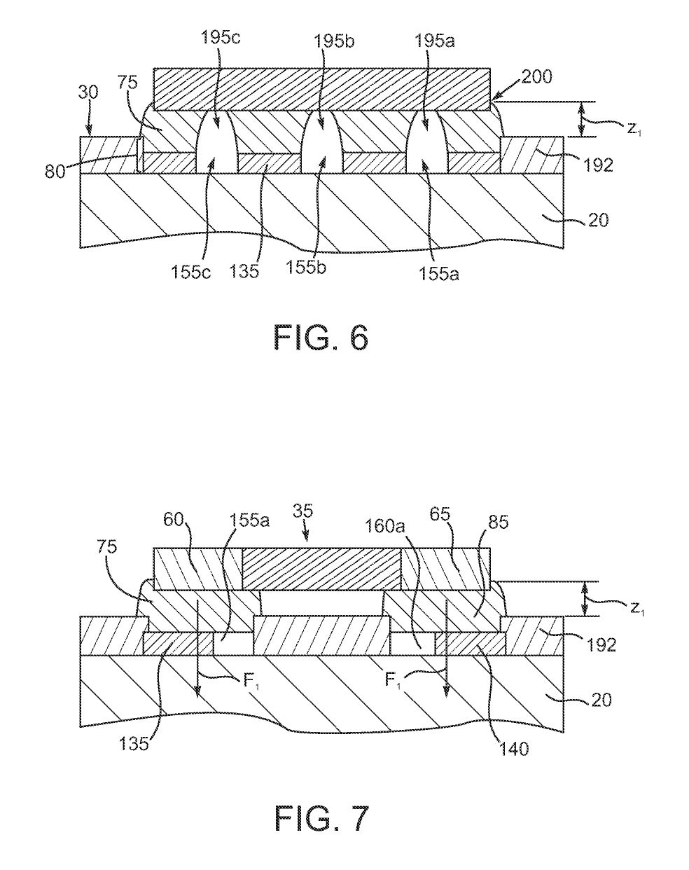

Additional details of the conductor pad 135 may be understood by referring now to FIG. 6, which is a sectional view of FIG. 4 taken at section 6-6. Note that section 6-6 passes lengthwise through the conductor pad 135 and includes the notches 155a, 155b and 155c. Furthermore, FIG. 6 depicts the conductor pad 135 and the circuit board 20 with the capacitor 35 and the solder portion 75 in place. Because of the location of section 6-6, the terminal 60 of the capacitor 35 is visible in section. As noted elsewhere herein, the conductor pad 135 is located in the opening 80 of the surface 30. In this illustrative embodiment, the surface 30 is the outer surface of a solder resist layer 192. For simplicity of illustration, only an upper portion of the circuit board 20 is depicted. In this way, the surface 45 and the ball grid array 25 of the circuit board 20 depicted in FIG. 1 are not shown. As noted above, the presence of the notches 155a, 155b and 155c of the conductor pad 135 limit the ability of the solder portion 75 to wet such that voids 195a, 195b and 195c form in the solder portion 75 following reflow to bond the terminal 60 of the capacitor 35. This has the effect of establishing a vertical dimension z₁ of the solder portion as measured from the upper surface 30 of the solder resist 192 to the upper extent 200 of the solder portion 75. By keeping the vertical dimension z₁ relatively low, the overall volume of the solder portion 75, particularly proximate the terminal 60, reduces the downward forces on the terminal 60 and thus reduces the potential for asymmetric forces. The same is true albeit on the opposite side for the notches 160a, 160b and 160c and the solder portion 85 depicted in FIG. 4.

The forces imparted on the terminals 60 and 65 of the capacitor 35 may be understood in more detail by referring now to FIG. 7, which is a sectional view of FIG. 4 taken at section 7-7. Note that section 7-7 passed through the solder mask layer 192, the notches 155a and 160a of the respective conductor pads 135 and 140 and both the terminals 60 and 65 of the capacitor 35. Here, and as noted above, the terminal 60 is metallurgically bonded to the solder portion 75 of vertical dimension z₁ and the terminal 65 is metallurgically bonded to the solder portion 85, also of vertical dimension z₁. The notches 155a and 160a (as well as the notches 155b, 155c, 160b and 160c visible in FIGS. 4 and 6) increase the probability that there will be the same or nearly the same resultant force F₁ imparted by the solder portion 75 on the terminal 60 and by the solder portion 85 on the terminal 65. Even if the forces acting on the terminals 60 and 65 by the solder portions 75 and 85 are not exactly equal, they will nevertheless be relatively small and thus reduce the propensity for there to be a force couple system which might cause an unwanted rotation of the capacitor 35 during solder reflow.

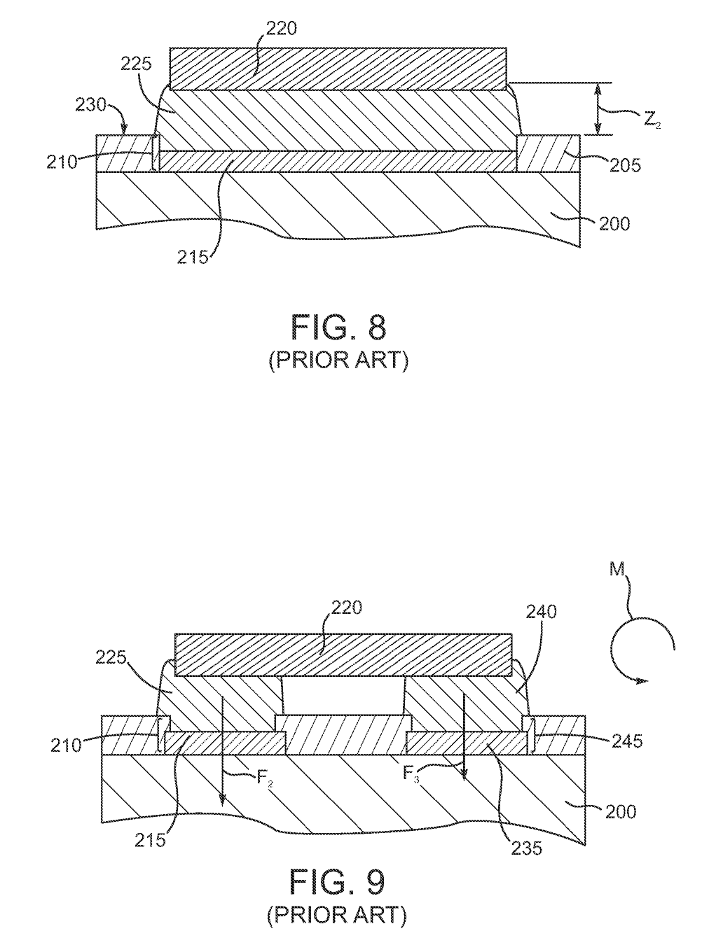

It may be useful at this juncture to contrast the disclosed embodiments with a conventional conductor pad, solder portion and passive component mounting scheme. FIG. 8 is a sectional view like FIG. 6, but of a conventional circuit board 200 fitted with a solder resist layer 205. The solder resist layer 205 is patterned with an opening 210 in which a conventional conductor pad 215 is positioned. The conductor pad 215 is of the conventional continuous footprint design as described generally above. A capacitor 220 is mounted to the conductor pad 215 by way of a solder portion 225 which, due to the conventional fully continuous footprint of the conductor pad 215, reflows to a vertical dimension Z₂ as measured from an upper surface 230 of the solder resist 205. A parallel solder portion and conductor pad that connect to the capacitor 220 will be shown in FIG. 9. Attention is now turned to FIG. 9, which shows the conductor pad 215 of the circuit board 20 connected to the solder portion 225 (as also visible in FIG. 8) and another a conductor pad 235 and a corresponding solder portion 240, which is metallurgically bonded to the conductor pad 235 and to the capacitor 220. Here, due to the potential for disparities between either the overall footprint size of the pads 215 and 235 and/or the openings 210 and 245 in the solder resist 205, there may be asymmetric forces F₂ and F₃ imparted by the solder portion 225 and the solder portion 240 on the capacitor 220. These asymmetric forces produce a moment M acting on the capacitor 220. If the magnitude of the moment M exceeds the weight of the capacitor 220, the capacitor movement in the direction of the moment M during solder flow can occur, leading to defects.

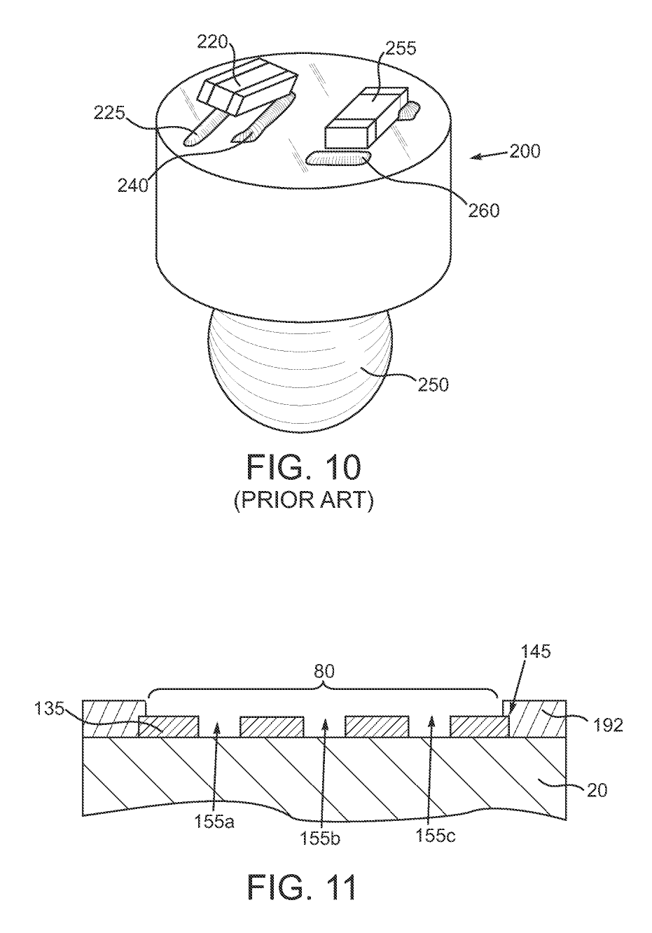

A couple of exemplary types of defects that may be produced by asymmetric forces may be understood by referring now to FIG. 10, which is a pictorial view of a small circular portion of the circuit board 200 of FIGS. 8 and 9 cut away, lifted out and shown in isolation. Here, the circuit board 200 may include a solder ball 250 and a pair of capacitors 220 and 255. The capacitor 220 is depicted with a tombstone defect in which the capacitor 220 is rotated around at least one axis, and possibly all three axes, and thus loses contact with the solder portion 225 and much of the solder portion 240. In addition, the capacitor 255 is depicted with a shift defect such that physical contact is lost with a solder portion 260 which results in an open circuit.

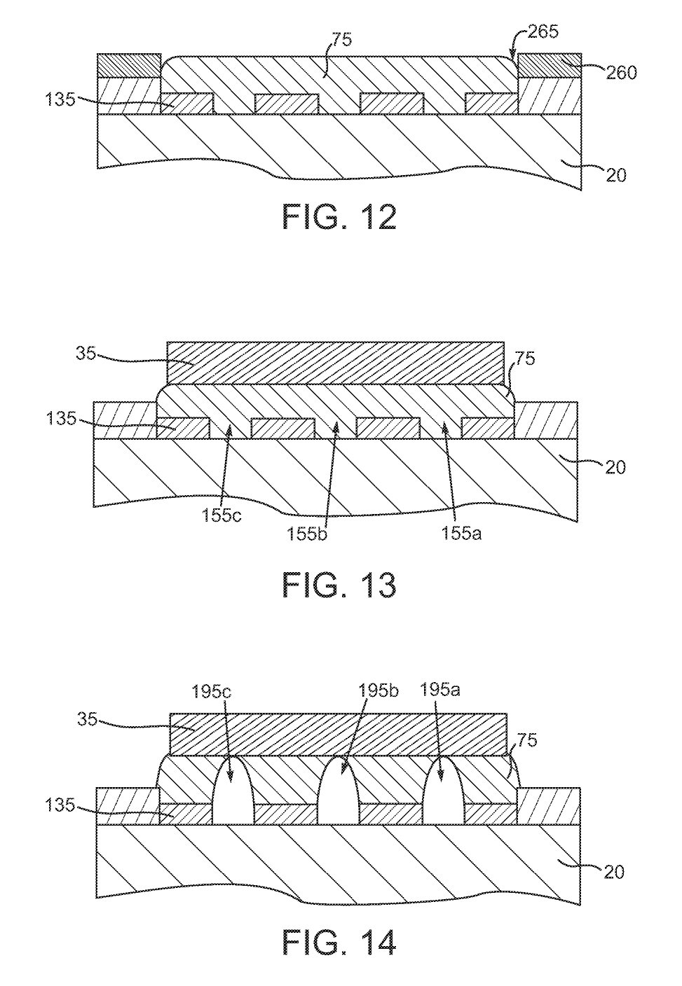

An exemplary method for fabricating any of the conductor pads disclosed herein may be understood by referring now to FIGS. 11, 12, 13 and 14 and initially to FIG. 11. The exemplary process will be described in conjunction with the fabrication of the conductor pad 135, but may also typify the other conductor pads disclosed herein as well. FIG. 11 is a sectional view of the portion of the circuit board 20 similar to FIG. 6. Here, the conductor pad 135 may be formed on the circuit board 20 in a variety of ways. In an exemplary embodiment, a plating process may be used to establish the conductor pad 135. In this regard, an electroless plating process may be used to initially establish a seed layer (not shown) that will serve as a plating terminal for a subsequent biased plating process. Next, a photolithography mask (not shown) may be applied and patterned with an opening shaped to correspond to the desired footprint of the conductor pad 135. A biased plating process is next performed to establish the conductor pad 135 with the requisite notches 155a, 155b and 115c. In another alternative, a conductor material may be applied to the circuit board 20 and thereafter patterned using a photolithographic mask and etch removal or laser ablation to form the notches 155a, 155b and 115c. Exemplary materials for the conductor pad 135 include copper, silver, gold, platinum, palladium, combinations of these or the like.

Next, the solder resist layer 192 may be applied to the circuit board 20. It should be understood that the solder resist layer 192 may be composed of suitable solder resist materials, such as, for example, PSR-4000 AUS703 manufactured by Taiyo Ink Mfg. Co., Ltd. or SR7000 manufactured by Hitachi Chemical Co., Ltd. To form the opening 80, the solder mask 192 may be lithographically patterned. If composed of solder resist, the solder mask layer 192 may be temporarily masked with a non-contact mask (not shown) and exposed with radiation. A developing process may be used to dissolve the opening 80. Optionally, some other form of insulating material may be used and patterned by photolithography and chemical etching or otherwise to establish the opening 80. In still another alternative, a stencil (not shown) may be placed on the circuit board 20 and a squeeze process used to apply material except where the opening 80 will be. Regardless of technique, the lateral border of the opening 80 may be vertically aligned or overlapping with the perimeter 145 of the conductor pad 35 as desired.

Next and as depicted in FIG. 10, the solder portion 75 is positioned in the opening 80. This step may be performed in a variety of ways. In an exemplary embodiment, a solder paste may be applied using a stencil 260 positioned on the solder mask 192 and provided with a suitable opening 265 sized appropriately. A suitable flux may be applied to the conductor pad 35 prior to the placement of the solder paste if desired. Following the application of the solder portion 75, the stencil 260 may be removed. Other techniques for solder application could be used, such as jet printing. The solder portion 75 may be composed of various types of solders, such as lead-free or lead-based solders. Examples of suitable lead-free solders include tin-silver (about 97.3% Sn 2.7% Ag), tin-copper (about 99% Sn 1% Cu), tin-silver-copper (about 96.5% Sn 3% Ag 0.5% Cu) or the like. Examples of lead-based solders include tin-lead solders at or near eutectic proportions or the like.

At this point, the capacitor 35 may be seated on the circuit board 20, and in particular on the solder portion 75, which is still in paste form as shown in FIG. 13. At this stage, no voids in the solder portion 75 are present in the vicinity of the notches 155a, 155b and 155c of the conductor pad 135. Next and as shown in FIG. 14, the circuit board 20 may be subjected to a reflow. The reflow will temporarily liquify the solder portion 75, liberate solvents and flux therefrom and cause wetting to the capacitor 35 and portions of the conductor pad 135 but not where the notches 155a, 155b and 155c are located. This preferential wetting leads to the formation of the aforementioned voids 195a, 195b and 195c in the solder portion 75. The voids 195a, 195b and 195c provide the desired substantially symmetric force system benefits as described elsewhere herein. The appropriate parameters for the reflow step will depend upon the composition of the solder portion 75 and the size of the circuit board 20 among other parameters.

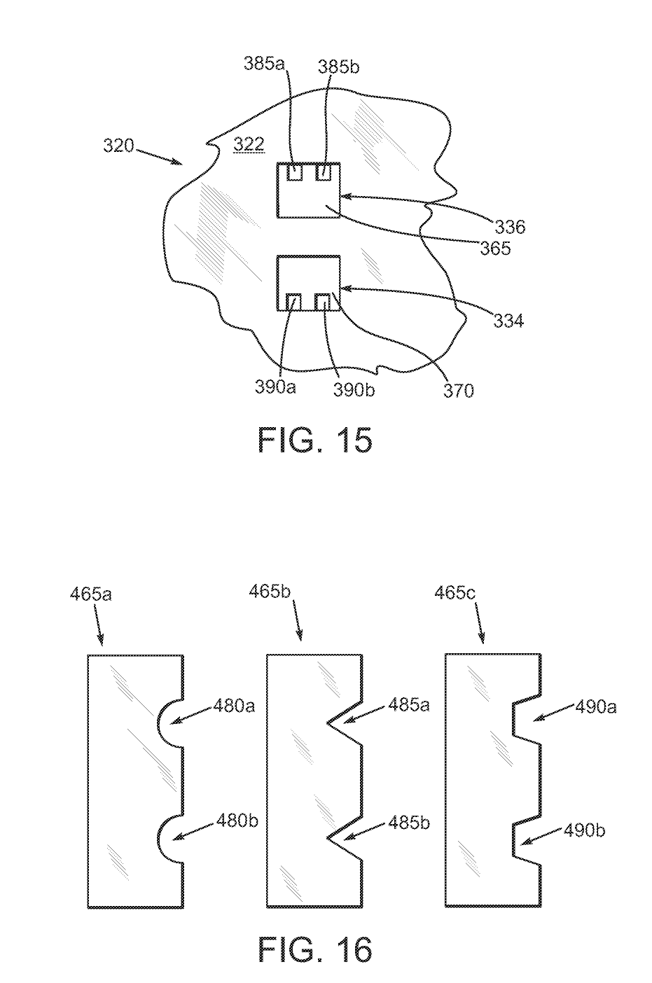

In the foregoing illustrative embodiments, the notches of a given conductor pad face toward an adjacent conductor pad and vice versa. However, conductor pads may be fabricated with notches that are on opposite sides. FIG. 15 is plan view of a small portion of a circuit board 320 that may be configured generally like the circuit board 20 depicted in other figures and described elsewhere herein. The circuit board 320 includes a solder resist layer 330 patterned with two openings 334 and 336 that reveal underlying conductor pads 365 and 370. The conductor pads 365 and 370 may be configured and fabricated like any of the other disclosed conductor pads, such as 165 and 170 in FIG. 4 for example, but with some differences. Here, the conductor pad 365 may be provided with notches 385a and 385b and the conductor pad 370 may be provided with notches 390a and 390b. However, the notches 385a and 385b do not face toward, but rather face away from the conductor pad 370 and vice versa for the notches 390a and 390b and the conductor pad 365. As with the other disclosed embodiments, the number and arrangement of notches 385a, 385b, 390a and 390b may be varied.

The skilled artisan will appreciate that notch design for a given conductor pad may be varied. FIG. 16 is a plan view of a few alternate exemplary conductor pads 465a, 465b and 465c. The conductor pad 465a may be provided with oval notches 480a and 480b, the conductor pad may be provided with triangular notches 485a and 485b and the conductor pad 465c may be provided with trapezoidal notches 490a and 490b. Of course, many other shapes may be used. The conductor pads 465a, 465b and 465c may be configured and fabricated in other aspects like the other disclosed conductor pads.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a first conductor pad on a circuit board, the first conductor pad including a first notch and being adapted to couple to a first solder portion.

2. The method of claim 1, comprising forming a second conductor pad on the circuit board, the second conductor pad including a second notch and being adapted to couple to a second solder portion.

3. The method of claim 2, comprising applying a first solder portion to the first conductor pad and a second solder portion to the second conductor pad and coupling a first terminal of a first electronic component to the first solder portion and a second terminal of the first electronic component to the second solder portion.

4. The method of claim 3, comprising coupling the first terminal over the first notch and the second terminal over the second notch.

5. The method of claim 3, wherein the electronic component comprises a passive component.

6. The method of claim 1, comprising forming the first conductor pad with plural notches.

7. The method of claim 1, comprising applying an insulating layer on the circuit board and forming an opening that exposes at least a portion of the conductor pad that includes the first notch.

8. The method of claim 1, wherein the first conductor pad is formed using instructions stored in a computer readable medium.

9. The method of claim 1, comprising coupling a semiconductor chip to the circuit board.

10. A method of manufacturing, comprising:
forming a first conductor pad and a second conductor pad on a circuit board, the first conductor pad being adapted to couple to a first solder portion and including a first notch facing toward the second conductor pad, the second conductor pad being adapted to couple to a second solder portion and including a second notch facing toward the first conductor pad.

11. The method of claim 10, wherein the first notch is aligned with the second notch.

12. The method of claim 10, comprising applying a first solder portion to the first conductor pad and a second solder portion to the second conductor pad and coupling a first terminal of a first electronic component to the first solder portion and a second terminal of the first electronic component to the second solder portion.

13. The method of claim 12, comprising coupling the first terminal over the first notch and the second terminal over the second notch.

14. The method of claim 12, wherein the electronic component comprises a passive component.

15. The method of claim 10, comprising forming the first conductor pad with a first plurality of notches and the second conductor pad with a second plurality of notches.

16. The method of claim 10, comprising coupling a semiconductor chip to the circuit board.

17. The method of claim 10, comprising applying an insulating layer on the circuit board and forming a first opening that exposes at least a portion of the first conductor pad that includes the first notch, and a second opening that exposes at least a portion of the second conductor pad that includes the second notch.

18. An apparatus, comprising:
a circuit board; and
a first conductor pad coupled to the circuit board, the first conductor pad including a first notch and being adapted to couple to a first solder portion.

19. The apparatus of claim 18, comprising a second conductor pad coupled to the circuit board, the second conductor pad including a second notch and being adapted to couple to a second solder portion.

20. The apparatus of claim 19, comprising a first solder portion coupled to the first conductor pad, and a second solder portion coupled to the second conductor pad, and a first electronic component including a first terminal coupled to the first solder portion and a second terminal coupled to the second solder portion.

21. The apparatus of claim 20, wherein the first terminal is positioned over the first notch and the second terminal is positioned over the second notch.

22. The apparatus of claim 20, wherein the electronic component comprises a passive component.

23. The apparatus of claim 18, wherein the first conductor pad comprises plural notches.

24. The apparatus of claim 18, comprising a semiconductor chip coupled to the circuit board.
